(19) United States
(12) Patent Application Publication
(10) Pub. No.: US 2007/0148898 A1
(43) Pub. Date: Jun. 28, 2007

(54) Method for Forming Capacitor

(76) Inventor: Kang Hyun Lee, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/613,215

(22) Filed: Dec. 20, 2006

(30) Foreign Application Priority Data
Dec. 28, 2005 (KR) 10-2005-0131630

(51) Int. Cl. H01L 21/467

(52) U.S. Cl. 438/396; 438/725

(57) ABSTRACT

A method for forming a capacitor is provided. In an embodiment of the method, a lower electrode of the capacitor is formed on a semiconductor substrate. An insulating layer and a metal layer are sequentially deposited on the lower electrode of the capacitor, and a photoresist pattern is formed on the metal layer. The metal layer is etched using the photoresist pattern as a mask to form an upper electrode of the capacitor and to form a polymer layer on a sidewall of the upper electrode of the capacitor. Subsequently, the insulating layer is etched using the photoresist pattern as a mask to form an insulating layer of the capacitor. The polymer layer formed on the sidewalls of the upper electrode of the capacitor is cleaned and removed.

This application claims priority under 35 U.S.C. §119(e) of Korean Patent Application No. 10-2005-0131630 filed Dec. 28, 2005, which is incorporated herein by reference in its entirety.

### FIELD OF THE INVENTION

The present invention relates to a method for forming a capacitor.

### BACKGROUND OF THE INVENTION

A merged memory logic (MML) is a device including a memory cell array (e.g., dynamic random access memory (DRAM)), an analog circuit, and a peripheral circuit integrated on a single chip.

Multimedia functions can be greatly improved by this MML, resulting in high integration and high speed of a semiconductor device.

Studies for realizing high capacity capacitors in analog circuits requiring high speed operation are constantly in progress.

In a related art capacitor having a polysilicon-insulator-polysilicon (PIP) structure, an upper electrode and a lower electrode are formed of conductive polysilicon. This leads to the occurrence of an oxidation reaction at an interface between upper/lower electrodes and a dielectric thin layer, which forms a natural oxide layer, resulting in reduced entire capacitance.

Also, reduction in capacitance caused by a depletion layer formed in a polysilicon layer is inappropriate for high speed and high frequency operation.

To solve this problem, a capacitor having a metal-insulator-metal (MIM) structure is used where an upper electrode and a lower electrode of the capacitor are formed of metal. Since the capacitor having the MIM structure has small specific resistance and no parasitic capacitance caused by depletion within the capacitor, it is primarily used for a high performance semiconductor device. The MIM capacitor is made by simultaneously forming the lower electrode of the capacitor with a metal line, and then forming an insulating layer of the capacitor and the upper electrode of the capacitor on the lower electrode. Generally, the insulating layer of the capacitor can be formed using a silicon nitride layer, and the upper electrode of the capacitor is formed of Ti/TiN.

A method for forming a MIM capacitor of a semiconductor device according to the related art will now be described below with reference to the accompanying drawings.

FIGS. 1A and 1B are cross-sectional views illustrating a method for forming an MIM capacitor according to the related art.

Referring to FIG. 1A, a metal conductive layer is deposited on a semiconductor substrate and patterned to form a lower electrode 31 and a lower line (not shown) of the capacitor. A barrier layer 21 is typically formed under the lower electrode 31 of the capacitor, and a diffusion barrier layer 22 is formed on the lower electrode 31 of the capacitor.

The lower electrode 31 of the capacitor can be formed of Al or Cu, and the barrier layer 21 and the diffusion barrier layer 22 can each be a stacking layer of Ti/TiN.

Next, an insulating layer 32 of the capacitor is formed by depositing a silicon nitride layer on the diffusion barrier layer 22. An upper electrode 33 of the capacitor is formed by depositing a stacking layer of Ti/TiN.

After that, referring to FIG. 1B, a photoresist pattern 50 is formed on the upper electrode 33 of the capacitor in order to pattern the insulating layer 32 and the upper electrode 33 of the capacitor. Subsequently, the insulating layer 32 and the upper electrode 33 of the capacitor are simultaneously dry-etched using the photoresist pattern 50 as a mask.

At this point, the etching is performed using reactive ion etching (RIE), where a chlorine-based gas is used for etching the upper electrode of the capacitor, and a fluorine-based gas is used for etching the insulating layer of the capacitor.

However, during the etching process, the capacitor insulating layer 32 may be overly etched and a TiN or Ti component is re-sputtered and erroneously deposited on sidewalls of the insulating layer.

The upper and lower electrodes of the capacitor become bridge-connected to each other by a metal component re-sputtered on the sidewalls of the insulating layer of the capacitor. This causes a current leakage, which reduces the performance of the capacitor.

That is, since RIE is used during a process of etching the insulating layer, a sidewall deposition problem caused by a TiN re-sputtering effect cannot be controlled.

This sidewall deposition problem leads to a severe reduction in a Vcc characteristic.

### BRIEF SUMMARY

Accordingly, embodiments the present invention are directed to a method for forming a capacitor that substantially obviates one or more problems due to limitations and/or disadvantages of the related art.

An object of the present invention is to provide a method for forming a capacitor, capable of preventing an upper electrode from being bridge-connected to a lower electrode during a process of manufacturing the capacitor.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for forming a capacitor, the method including: forming a lower electrode of the capacitor on a semiconductor substrate; sequentially depositing an insulating layer and a metal layer on the lower electrode of the capacitor; forming a photoresist pattern on the metal layer; etching the metal layer using the photoresist pattern as a mask to form an upper electrode of the capacitor, wherein a polymer layer is formed on a sidewall of the upper electrode of the capacitor; etching the insulating layer using the photoresist pattern as a mask to form an insulating layer of the capacitor; and cleaning and removing the polymer layer formed on the sidewall of the upper electrode of the capacitor.

In another aspect of the present invention, there is provided a method for forming a capacitor, the method including: forming a lower electrode of the capacitor on a semiconductor substrate; sequentially depositing an insulating layer and a metal layer on the lower electrode of the capacitor; forming a photoresist pattern on the metal layer; etching the metal layer and the insulating layer using the photoresist pattern as a mask to form an upper electrode of the capacitor and an insulating layer of the capacitor, wherein a polymer layer is formed on a sidewall of the upper electrode of the capacitor and the insulating layer of the capacitor; and cleaning and removing the polymer layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIGS. 1A and 1B are cross-sectional views for explaining a method for forming an MIM capacitor according to the related art.

FIGS. 2A to 2C are cross-sectional views for explaining a method for forming a capacitor according to a first embodiment of the present invention.

FIGS. 3A to 3D are cross-sectional views for explaining a method for forming a capacitor according to a second embodiment of the present invention.

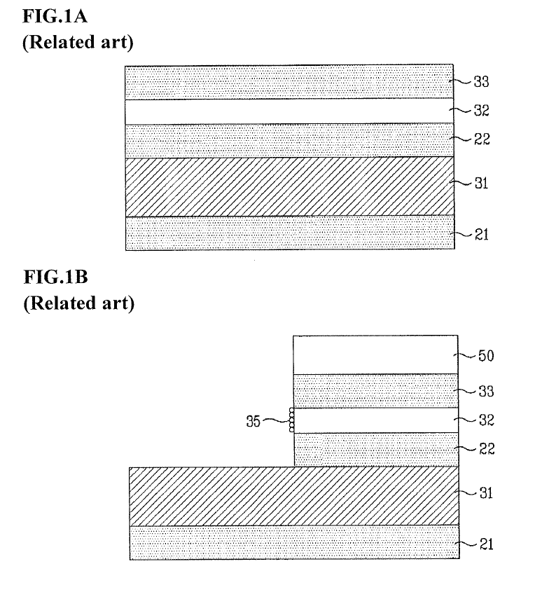

### DETAILED DESCRIPTION OF THE INVENTION

Reference will now be made in detail to the preferred embodiments of the present invention, examples of which are illustrated in the accompanying drawings.

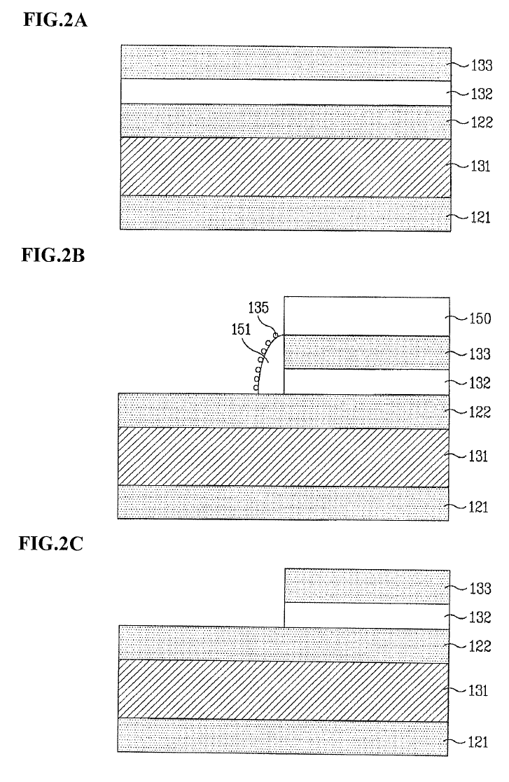

FIGS. 2A to 2C are cross-sectional views for explaining a method for forming a capacitor according to a first embodiment of the present invention.

First, referring to FIG. 2A, after an insulating layer (not shown) is deposited and damascene patterns are formed on a semiconductor substrate having a predetermined structure, a stacking layer of TiN/Ti can be deposited on an inner surface of the damascene patterns to form a barrier layer 121, and may form aluminum gap-fills on the barrier layer 121.

The barrier layer 121 can be a layer formed of Ta, TaN, WN, TaC, WC, TiSiN, or TaSiN, besides the stacking layer of TiN/Ti. The barrier layer can be deposited using, for example, physical vapor deposition (PVD), chemical vapor deposition (CVD), or atomic layer deposition (ALD).

Subsequently, a chemical mechanical polishing (CMP) can be performed until an upper surface of the insulating layer is exposed to form a metal line (not shown) and a lower electrode 131 of the capacitor. That is, the metal line and the lower electrode 131 of the capacitor can be simultaneously formed using a damascene process.

After that, a stacking layer of TiN/Ti can be deposited on the lower electrode 131 of the capacitor to a thin thickness using, for example, CVD, PVD, or ALD to form a diffusion barrier layer 122 for preventing metal of the metal line and the lower electrode 131 of the capacitor from diffusing into the insulating layer.

Next, a layer of a material having a high dielectric constant, e.g., a plasma enhanced (PE)-based material such as PE-SiN, PE-SiH₄, and PE-SiON, can be deposited on the diffusion barrier layer 122 using, for example, CVD, PVD, or ALD, to form an insulating layer 132 of the capacitor. Also, a stacking layer of TiN/Ti can be deposited on the insulating layer 132 of the capacitor using, for example, CVD, PVD, or ALD to form an upper electrode 133 of the capacitor.

Materials and thicknesses of the insulating layer of the capacitor and the upper electrode of the capacitor are determined with consideration of device characteristics of a surface current and Vcc.

After that, referring to FIG. 2B, a photoresist can be coated on the upper electrode 133 of the capacitor and patterned using photolithography to form a desired photoresist pattern 150.

Next, the upper electrode 133 of the capacitor can be dry-etched using the photoresist pattern 150 as a mask by a RIE that uses a chlorine-based gas. The chlorine-based gas can be C1₂ or BC1₃ gas.

At this point, a polymer layer 151 may be formed on a sidewall of the upper electrode 133 of the capacitor.

That is, during a process of etching the metal layer to form the upper electrode of the capacitor, the photoresist pattern is simultaneously etched and photoresist pattern particles are created. Such carbon-based particles are deposited on the sidewall of the upper electrode of the capacitor to become a polymer layer 151.

Strong bias power of an etching equipment can be provided so that etching selectivity is small with respect to the photoresist pattern during the process of etching the metal layer to form the upper electrode of the capacitor in order to allow the photoresist pattern to be etched when the upper electrode of the capacitor is etched.

After that, the insulating layer is etched using the same photoresist pattern 150 as a mask and using a gas of CH₃F as an etch gas to form a pattern of the insulating layer 132 of the capacitor. At this point, the polymer layer 151 continues to form by allowing polymer to be created inside the etching equipment using a gas of CH₃F as an etch gas.

Therefore, when the insulating layer 132 of the capacitor is etched, the lower electrode of the capacitor may be ov erly etched, so that metal particles (e.g., TiN) of the diffusion barrier 122 are re-sputtered. The re-sputtered metal particles 135 are not deposited on the sidewall of the insulating layer of the capacitor but, rather, are deposited on the polymer layer 151.

The metal particles deposited on the polymer layer can be removed together with the polymer layer through a cleaning process. Since the polymer layer is formed of the same material as that of the photoresist pattern, it can be simultaneously removed with the photoresist pattern.

Therefore, a desired portion of the insulating layer of the capacitor can be completely removed without problems caused by re-sputtering of the metal particles, and an anti-reflection film is not required when a lower layer to which the lower electrode of the capacitor belongs is patterned.

The etching of the metal layer to form the upper electrode of the capacitor, and the etching the insulating layer to form the insulating layer of the capacitor can be simultaneously performed in an in-situ manner. In this case, during the etching the metal layer and the etching the insulating layer, the photoresist pattern is simultaneously etched to form the polymer layer on sidewalls of the upper electrode of the capacitor and the insulating layer of the capacitor.

That is, the polymer layer can be simultaneously formed during the etching processes by providing a strong bias power to the etching equipment so that etching selectivity with respect to the photoresist pattern is small when the upper electrode of the capacitor is etched, and making a carbon-based polymer abundant inside the etching equipment using a gas of CH₃F as an etch gas when the insulating layer of the capacitor is etched.

By doing so, referring to FIG. 2C, a MIM capacitor including the lower electrode 131 of the capacitor, the insulating layer 132 of the capacitor, and the upper electrode 133 of the capacitor can be completed. Although not shown in the figures, the upper and lower electrodes of the capacitor receive a bias via a contact plug.

Also, though not shown, after the photoresist is deposited on the lower electrode of the capacitor and patterned, a lower layer to which the lower electrode of the capacitor belongs can be patterned using the photoresist pattern as a mask. At this point, since the insulating layer of the capacitor does not remain on the lower electrode of the capacitor, an anti-reflection film for compensating for a low adhesive characteristic between the insulating layer of the capacitor and the photoresist pattern is not required. Accordingly, all processes associated with the anti-reflection film can be omitted.

Subsequently, when a logic section is completed through various wiring processes and a transistor process, a semiconductor device can be finally manufactured.

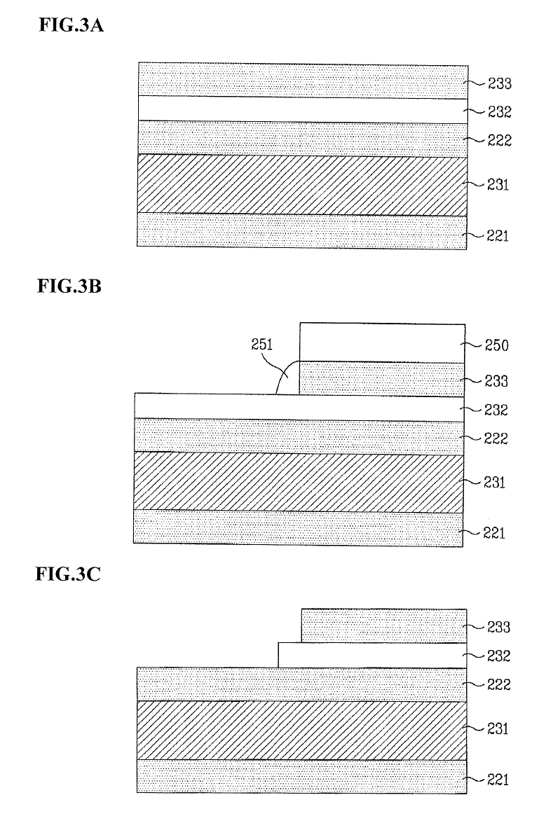

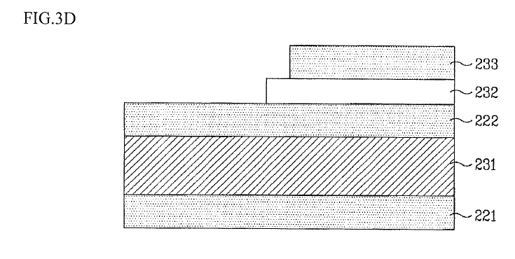

FIGS. 3A to 3D are cross-sectional views for explaining a method for forming a capacitor according to a second embodiment of the present invention.

First, referring to FIG. 3A, after an insulating layer (not shown) is deposited and damascene patterns are formed on a semiconductor substrate (not shown) having a predetermined structure, a stacking layer of TiN/Ti can be deposited on an inner surface of the damascene patterns to form a barrier layer 221, and may form aluminum gap-fills on the barrier layer 221.

The barrier layer 221 can be a layer formed of Ta, TaN, WN, TaC, WC, TiSiN, or TaSiN, besides the stacking layer of TiN/Ti. The barrier layer can be deposited using, for example, physical vapor deposition (PVD), chemical vapor deposition (CVD), or atomic layer deposition (ALD).

Subsequently, a CMP process can be performed until an upper surface of the insulating layer is exposed to form a metal line (not shown) and a lower electrode 231 of the capacitor. That is, the metal line and the lower electrode 231 of the capacitor can be simultaneously formed using a damascene process.

After that, a stacking layer of TiN/Ti can be deposited on the lower electrode 231 of the capacitor to a thin thickness using, for example, CVD, PVD, or ALD to form a diffusion barrier layer 222 for preventing metal of the metal line and the lower electrode 231 of the capacitor from diffusing into the insulating layer.

Next, a layer of a material having a high dielectric constant, e.g., a PE-based material such as PE-SiN, PE-SiH₄, and PE-SiON can be deposited on the diffusion barrier layer 222 using, for example, CVD, PVD, or ALD to form an insulating layer 232 of the capacitor. Also, a stacking layer of TiN/Ti can be deposited on the insulating layer 232 of the capacitor using, for example, CVD, PVD, or ALD to form an upper electrode 233 of the capacitor.

Materials and thicknesses of the insulating layer of the capacitor and the upper electrode of the capacitor are determined with consideration of device characteristics of a surface current and Vcc.

After that, referring to FIG. 3B, a photoresist can be coated on the upper electrode 233 of the capacitor and patterned using photolithography to form a desired photoresist pattern 250.

Next, the upper electrode 233 of the capacitor can be dry-etched using the photoresist pattern 250 as a mask by a RIE that uses a gas of C1₂ or BC1₃ as an etch gas.

Subsequently, a polymer layer 251 can be formed by depositing polymer on a sidewall of the upper electrode of the capacitor using a gas of C₅F₈ or C₄F₈.

Next, referring to FIG. 3C, the insulating layer can be etched using the same photoresist pattern 250 and the polymer layer 251 as a mask. A gas of CH₃F can be used as an etch gas to complete a pattern of the insulating layer 232 of the capacitor. At this point, a portion of the insulating layer 232 that is located under the polymer layer 251 remains.

As described above, the polymer layer 251 is formed on the sidewall of the upper electrode of the capacitor. When the insulating layer 232 of the capacitor is etched, the lower electrode of the capacitor may be ov erly etched, so that metal particles (e.g., TiN) of the diffusion barrier 222 are re-sputtered. The re-sputtered metal particles 235 are not deposited on the sidewall of the insulating layer 232 of the capacitor but, rather, are deposited on the polymer layer 251.

The metal particles deposited on the polymer layer can be removed together with the polymer layer through a cleaning process. Since the polymer layer is formed of the same material as that of the photoresist pattern, it can be simultaneously removed with the photoresist pattern.

Therefore, a desired portion of the insulating layer of the capacitor can be completely removed without the problems caused by the re-sputtering of the metal particles, and an anti-reflection film is not required when a lower layer to which the lower electrode of the capacitor belongs is patterned.

Because the polymer layer is formed after the upper electrode of the capacitor is formed, the etching of the metal layer to form the upper electrode of the capacitor, and the etching of the insulating layer to form the insulating layer of the capacitor is not performed simultaneously.

Referring to FIG. 3D, a MIM capacitor including the lower electrode 231 of the capacitor, the insulating layer 232 of the capacitor, and the upper electrode 233 of the capacitor can be completed. Although not shown in the figures, the upper and lower electrodes of the capacitor receive a bias via a contact plug.

Also, though not shown, after the photoresist is deposited on the lower electrode of the capacitor and patterned, a lower layer to which the lower electrode of the capacitor belongs is patterned using the photoresist pattern as a mask. At this point, since the insulating layer of the capacitor does not remain on the lower electrode of the capacitor, an anti-reflection film for compensating for a low adhesive characteristic between the insulating layer of the capacitor and the photoresist pattern is not required. Accordingly, all processes associated with the anti-reflection film can be omitted.

Subsequently, when a logic section is completed through various wiring processes and a transistor process, a semiconductor device can be finally manufactured.

The above-described methods for forming the capacitor provide the following effects.

First, since a polymer layer is formed on a sidewall of an upper electrode of a capacitor, metal particles re-sputtered when a lower electrode of the capacitor is etched are deposited on the polymer layer. The polymer layer on which the metal particles from re-sputtering are deposited is removed during a subsequent cleaning process.

Therefore, it is possible to prevent metal particles re-sputtered when a lower electrode of a capacitor is etched from being deposited on an insulating layer of a capacitor. Thus, the upper and lower electrodes of the capacitor can be prevented from being bridge-connected to each other.

The polymer layer can be separately deposited on the sidewall of the upper electrode of the capacitor after the upper electrode of the capacitor is formed. Also, the polymer layer can be naturally formed by providing strong bias power to allow a photoresist pattern to be simultaneously etched when the upper electrode of the capacitor is etched.

Second, since the insulating layer of the capacitor can be completely removed without the effects of re-sputtering of metal particles from a lower layer, an anti-reflection film is not required when the lower layer to which the lower electrode of the capacitor belongs is patterned.

Therefore, manufacturing costs can be reduced, an additional process for etching and ashing an anti-reflection film does not need to be performed, and it is possible to prevent equipment from being contaminated from carbon-based foreign substances generated when the anti-reflection film is etched.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for forming a capacitor, comprising:
forming a lower electrode of a capacitor on a semiconductor substrate;
sequentially depositing an insulating layer and a metal layer on the lower electrode;
forming a photoresist pattern on the metal layer;
etching the metal layer using the photoresist pattern as a mask to form an upper electrode of the capacitor and forming a polymer layer on a sidewall of the upper electrode;
etching the insulating layer using the photoresist pattern as a mask to form an insulating layer of the capacitor; and
cleaning and removing the polymer layer formed on the sidewall of the upper electrode.

2. The method according to claim 1, wherein the polymer layer is formed by simultaneously etching the photoresist pattern during the etching of the metal layer using the photoresist pattern as a mask.

3. The method according to claim 1, wherein etching the insulating layer comprises using a gas of CH₃F as an etch gas.

4. The method according to claim 1, wherein the polymer layer is formed by depositing a polymer on the sidewall of the upper electrode of the capacitor using a gas of C₅H₈ or C₄H₈.

5. The method according to claim 1, wherein etching the metal layer comprises using a gas of C1₂ or BC1₃ as an etch gas.

6. The method according to claim 1, wherein a portion of the insulating layer that is located under the polymer layer is not etched during the etching of the insulating layer to form the insulating layer of the capacitor.

7. The method according to claim 1, further comprising forming a diffusion barrier layer of TiN/Ti on the lower electrode of the capacitor.

8. A method for forming a capacitor, comprising:
forming a lower electrode of a capacitor on a semiconductor substrate;
sequentially depositing an insulating layer and a metal layer on the lower electrode of the capacitor;
forming a photoresist pattern on the metal layer;
etching the metal layer and the insulating layer using the photoresist pattern as a mask to form an upper electrode of the capacitor and an insulating layer of the capacitor and to form a polymer layer on sidewalls of the upper electrode of the capacitor and the insulating layer of the capacitor; and
cleaning and removing the polymer layer.

9. The method according to claim 8, wherein the polymer layer is formed by simultaneously etching the photoresist pattern during the etching of the metal layer and the insulating layer using the photoresist pattern as a mask.

10. The method according to claim 8, wherein etching the insulating layer comprises using a gas of CH₃F as an etch gas.

11. The method according to claim 8, wherein the polymer layer is formed by depositing a polymer on the sidewall of the upper electrode of the capacitor using a gas of C₅H₈ or C₄H₈.

12. The method according to claim 8, wherein etching the metal layer comprises using a gas of Cl₂ or BCl₃ as an etch gas.

13. The method according to claim 8, further comprising forming a diffusion barrier layer of TiN/Ti on the lower electrode of the capacitor.
